(19) United States
(12) Patent Application Publication
(10) Pub. No.: US 2003/0122563 A1
(43) Pub. Date: Jul. 3, 2003

(54) Probe card and method for manufacturing the same

(76) Inventors: Choon-Leong Lou, Singapore (SG); Mei-Shu Hsu, Pa-Teh City (TW)

Correspondence Address: SEYFARTH SHAW, 55 EAST MONROE STREET, SUITE 4200, CHICAGO, IL, 60603-5803, US

(21) Appl. No.: 10/282,879

(22) Filed: Oct. 29, 2002

(30) Foreign Application Priority Data
Dec. 31, 2001 (TW) 090133498

(51) Int. Cl. G01R 31/02

(52) U.S. Cl. 324/754

(57) ABSTRACT

The present invention discloses a probe card, which includes one substrate and one conductive layer with a circuit pattern on the conductive layer. The probe card is characterized in that a gap is located between the circuits of the circuit pattern. The gap has a predetermined depth from the surface level of the substrate to isolate the circuits by the air to increase the resistance of the probe card and reduce the parasitic capacitance so as to improve the precision of the measurement. Since the gaps between the circuit patterns are formed by an engraving process, the leakage current effect due to a fault etching in prior art is avoided thereof.

### BACKGROUND OF THE INVENTION

1. Field of the Invention

The present invention relates to a probe card and method for manufacturing the same, and more particularly, to an air-gap type of probe card and method for manufacturing the same.

2. Background of the Invention

A conventional probe card for testing a semiconductor wafer uses an isolation material as a substrate. Most of the isolation materials including polyamide with glass fiber or epoxy resin (such as FR-4) are the common material used in manufacturing printed circuit board. As shown in FIG. 1, a conventional probe card 10 includes a conductive layer 12 on the surface of the substrate 11, an insulation pattern 13 is formed on the conductive layer 12 by an etching process, and the conductive layer 12 is generally made of metallic copper. However, the conventional probe card 10 causes the following drawbacks during a testing:

(1) High current leakage: the conventional probe card 10 uses an isolation substrate that is commonly used in printed circuit board, and uses only an isolation pattern 13 to isolate circuits on the conductive layer. Since the resistance of the substrate used in printed circuit board is too low, a current flows between circuits on the conductive layer 12 through the substrate, the current leakage effect occurs (normally higher than 10⁻¹² A), and errors occur on measuring a DC current parameter.

(2) High parasitic capacitance: the conventional probe card 10 mostly utilizes the multi-layer circuit design that results in very high parasitic capacitance due to the overlap of circuits in the conductive layer 12. Generally speaking, high parasitic capacitance causes errors on measuring a capacitance parameter, increases the test cost, and cannot measure a low capacitance parameter precisely.

(3) Unsuitable for high temperature measurement: the substrate such as polyamide or FR-4 glass fiber substrate used in the conventional probe card 10 will expand as the temperature increases, so that the probe card 10 can not provide a precise contact on the wafer and is not suitable for performing a measuring at high temperature.

Besides, since the isolation pattern 13 of the conventional probe card 10 is formed by an etching process, it is easy to cause errors in the circuit design of the conductive layer 12 due to a fault etching, and to further influence the quality of the DC and the AC parameter measurement.

Furthermore, the present semiconductor wafer test tends to request a high precision measurement, such as high impedance, low current, low voltage, low capacitance, etc. To solve the drawbacks in the conventional probe card 10 and to meet the current trend, the present invention discloses a circuit design using air-gap to enhance the reliability and stability of the parameter testing, to reduce testing period, and to further increase the competitive power of a wafer fab.

### SUMMARY OF THE INVENTION

Accordingly, the first object of the present invention is to provide a method for manufacturing a probe card. The present invention uses an engraving process to form an isolation pattern on the probe card in order to avoid errors in the circuit design and current leakage effect due to a fault etching.

The second object of the present invention is to provide an air-gap type of probe card. Since the air has the characteristics of the lowest dielectric permittivity and the highest resistance in all kinds of matter, using air as the isolation between circuits will decrease the parasitic capacitance between circuits to the lowest level, and increase the resistance between circuits.

The third object of the present invention is to provide a probe card using ceramic as the substrate. Since the ceramic itself has the characteristic of excellent isolation, the probe card made of ceramic substrate will meet the requirement of high impedance and low current during testing as the integrity of the semiconductor increases. Furthermore, since the ceramic substrate is more robust than the glass fiber substrate, it can endure the pressure of engraving and is not easy to deform, and it is suitable as the material of the substrate.

To achieve the above objects and to avoid drawbacks in prior art, the present invention provides a method for manufacturing a probe card, which comprises the following steps:

a. providing a substrate with a conductive layer on the surface of the substrate;

b. forming a circuit pattern on the conductive layer; and

c. forming at least a gap between circuits according to the circuit pattern of the conductive layer wherein the gap has a predetermined depth from the surface level of the substrate to isolate the circuits by the air.

Furthermore, the present invention also discloses a probe card, which comprises at least one substrate and at least one conductive layer with a circuit pattern on the conductive layer. The probe card is characterized in that a gap is located between the circuits of the circuit pattern. The gap has a predetermined depth from the surface level of the substrate for isolating the circuits by the air to increase the resistance of the probe card and reduce the parasitic capacitance so as to improve the precision of the measurement.

### BRIEF DESCRIPTION OF THE DRAWINGS

The present invention will be described according to the appended drawings in which:

FIG. 1 is a cross-sectional view of a probe card according to the prior art;

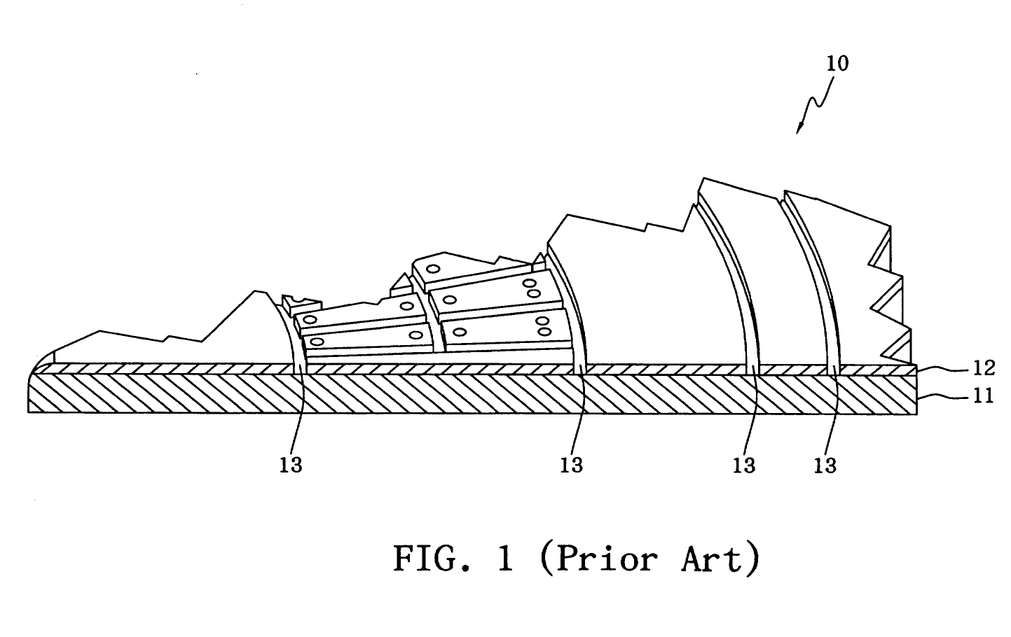

FIG. 2 is a cross-sectional view of a probe card according a preferred embodiment of the present invention;

FIG. 3a to FIG. 3c are flow charts for manufacturing a probe card according to the present invention;

FIG. 4 is a cross-sectional view of a probe card according to another embodiment of the present invention; and

FIG. 5 is a diagram comparing the impedance of the present invention and the prior art.

### DESCRIPTION OF PREFERRED EMBODIMENTS

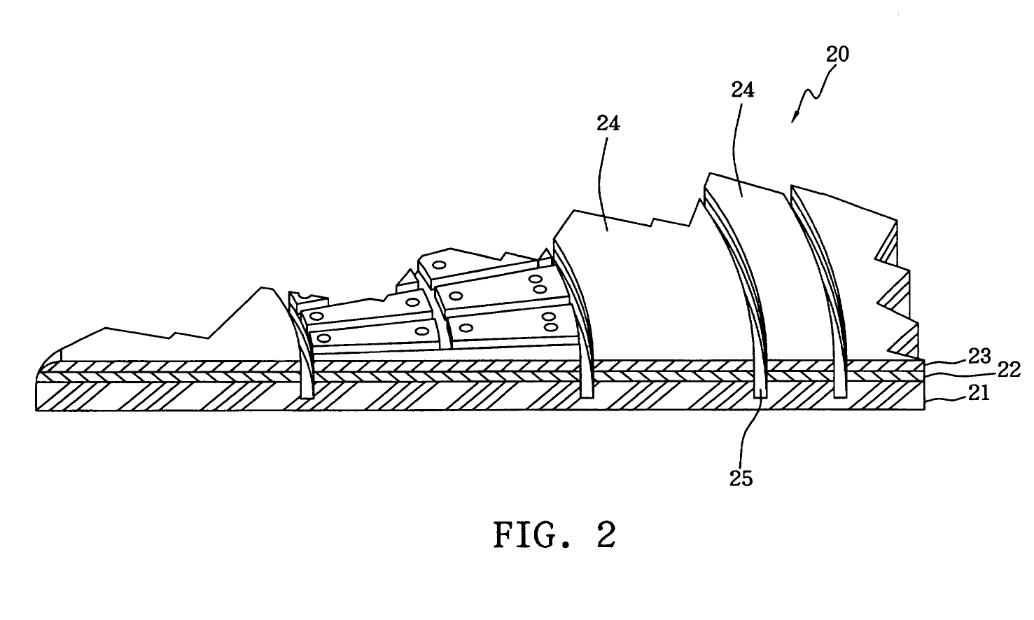

FIG. 2 is a cross-sectional view of a probe card 20 according to the first embodiment of the present invention. The probe card 20 comprises a substrate 21 and a conductive layer 22. Since the ceramic material has a better isolation effect than the substrate of the normal printed circuit board, the present invention selectively uses the ceramic material as the substrate 21. The conductive layer 22 is a metallic sheet such as a copper sheet. The surface of the conductive layer 22 may further include an electroplating layer 23 to prevent the conductive layer 22 from oxidizing by contacting the air. The electroplating layer 23 may be formed by an electroplating process to deposit a conductive metal on the surface of the conductive layer 22 wherein the metal used in electroplating is selected from the group consisted of Au, Ag, Ni, Pd, Cu and the alloy thereof.

Furthermore, a circuit pattern 24 is formed on the surface of the conductive layer 22. There is a gap 25 between the circuits of the circuit pattern 24, and the gap 25 has a depth from the surface level of the substrate wherein the depth is between 0.3 mm and 1.5 mm, preferably between 0.7 mm and 1.0 mm. The air in the gap 25 serves as the isolation between the circuits to greatly reduce the influence of current leakage. Besides, the probe card 20 disclosed in the present invention may also have a multi-layer structure, which is not confined in the present invention.

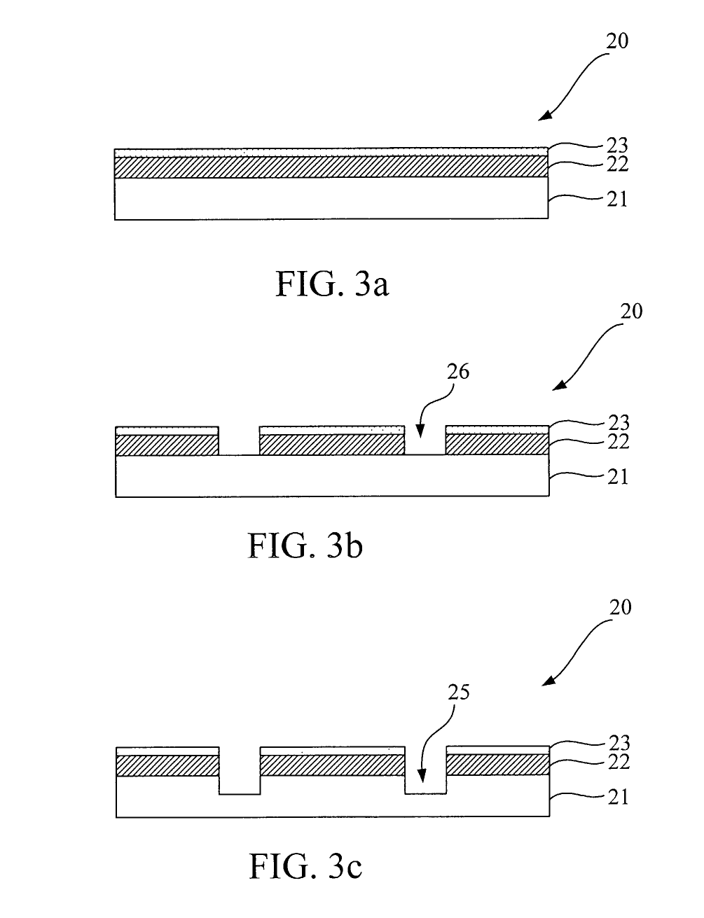

FIGS. 3a to 3c show the flow charts for manufacturing the probe card 20 according to the present invention. As shown in FIG. 3a, a substrate 21 with a conductive layer 22 is provided wherein the substrate 21 is made of ceramic material and the conductive layer 22 is a metallic sheet. The surface of the conductive layer 22 is coated with an electroplating layer 23 to prevent the conductive layer 22 from oxidizing by contacting the air.

As shown in FIG. 3b, an engraving process is then performed to form the isolation area 26 between circuits on the conductive layer 22 and the electroplating layer 23. Since the mechanical properties of the substrate 21 and conductive layer 22 are different, it is better not to engrave the substrate 21 and the conductive layer 22 by the same tool and the same rotational speed. Since both the electroplating layer 23 and the conductive layer 22 are made of soft metal, and the electroplating layer 23 is tightly adhered to the surface of the conductive layer 22 by electroplating with good binding force between each other, the engraving process for the electroplating layer 23 and the conductive layer 22 can be performed simultaneously.

Additionally, since the electroplating layer 23 and conductive layer 22 are quite good in the extensibilities, it should be performed with sharper graver at higher rotational speed during engraving these two layers. Generally speaking, the rotational speed is between 4000 to 12000 rpm, preferably between 8000 to 10000 rpm. If the rotational speed of the graver is not high enough, a crude edge may be easily produced in the electroplating layer 23 and the conductive layer 22 during the engraving process, or the electroplating layer 23 may be peeled off to cause the conductive layer 22 to oxidize and peel off by contacting with air and further affect the electrical property of the probe card 20. The repetitive engraving processes on the electroplating layer 23 and the conductive layer 22 is performed to form the isolation area 26. The isolation area 26 may penetrate the conductive layer 22 to expose part of the substrate 21.

As shown in FIG. 3c, the engraving process is performed on the exposed region of the substrate 21 to form a gap 25 between circuits according to the isolation area 26 on the conductive layer 22, and the gap 25 has a depth from the surface level of the substrate 21. Since the substrate 21 of the present invention is made of ceramic material and the ceramic material has the characteristics of high hardness and fragility, the graver with higher hardness is needed to engrave the substrate 21, and the rotational speed of the graver is between 5000 and 7000 rpm. As a result, the gap 25 can generate air isolation effect to isolate circuits. The depth of the gap 25 is between 0.3 mm to 1.5 mm, preferably between 0.7 mm to 1.0 mm, so that the circuits can be completely isolated and the current leakage effect can be greatly reduced.

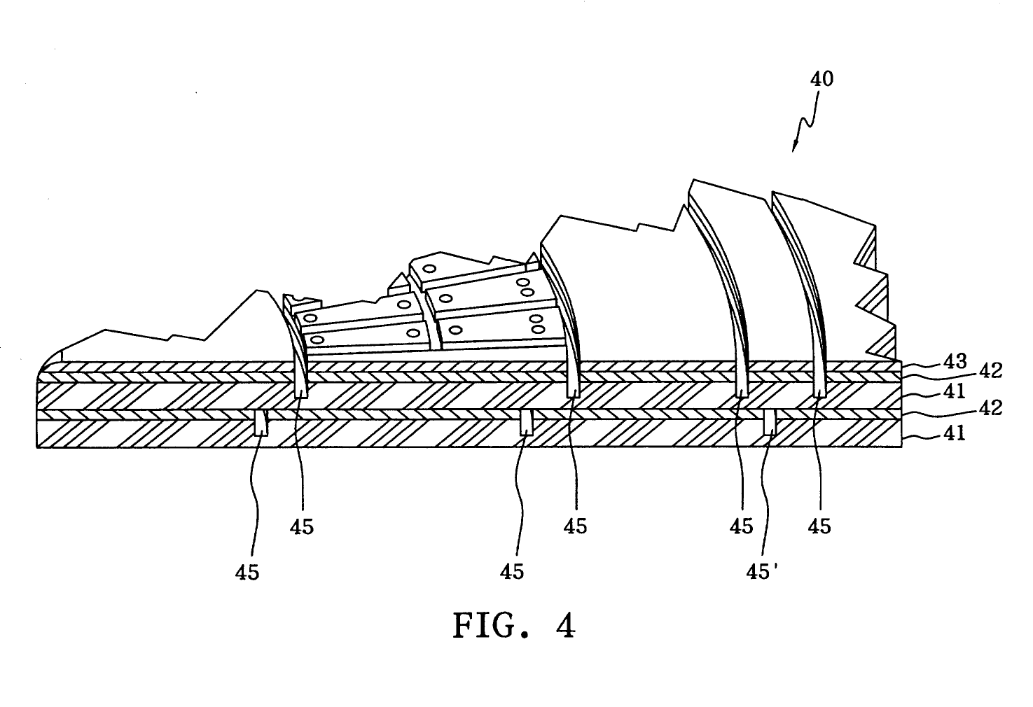

FIG. 4 shows the cross-sectional view of the probe card 40 according to the second embodiment of the invention. In the present embodiment, the probe card 40 has a multi-layer structure including two substrates 41, 41′ and two conductive layers 42, 42′. The surface of the conductive layer 42 further includes an electroplating layer 43. The surfaces of the conductive layers 42 and 42′ have a circuit pattern respectively (not shown), and the gaps 45 and 45′ are located between the circuits of the circuit pattern respectively to achieve the air isolation effect.

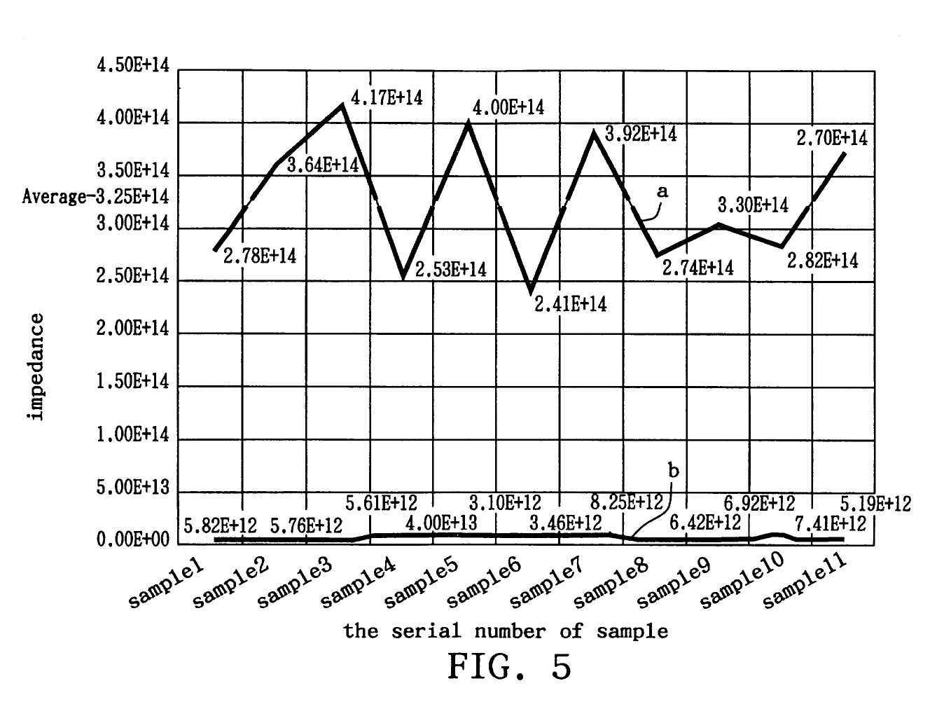

FIG. 5 shows a diagram comparing the impedance of the probe card of the present invention and the prior art. Curve-a represents the impedance measured by the probe card of the present invention and Curve-b represents the impedance measured by the conventional probe card. The air-gap type of probe card of the present invention can achieve higher impedance value, and the current leakage and parasitic capacitance may be greatly reduced.

The above-described embodiments of the present invention are intended to be illustrative only. Numerous alternative embodiments may be devised by those skilled in the art without departing from the scope of the following claims.

What is claimed is:

1. A probe card for testing a semiconductor, comprising:
at least one substrate; and
at least one conductive layer disposed on a surface of the substrate, wherein the conductive layer includes a circuit pattern, and adjacent circuits of the circuit pattern are isolated by a gap with a predetermined depth from the surface level of the substrate.

2. The probe card for testing a semiconductor of claim 1, wherein the substrate comprises ceramic.

3. The probe card for testing a semiconductor of claim 1, wherein the conductive layer is a metallic sheet.

4. The probe card for testing a semiconductor of claim 1, wherein an electroplating layer is formed on the surface of the conductive layer.

5. The probe card for testing a semiconductor of claim 4, wherein the electroplating layer is made of materials selected from the group essentially consisting of gold, silver, nickel, palladium, copper and the alloy thereof.

6. The probe card for testing a semiconductor of claim 1, wherein the predetermined depth of the gap is between 0.3 mm and 1.5 mm.

7. The probe card for testing semiconductor of claim 1, wherein the predetermined depth of the gap is preferably between 0.7 mm and 1.0 mm.

8. A method for manufacturing a probe card, comprising the steps of:
providing a substrate with a conductive layer disposed on the surface of the substrate;
forming at least one gap between adjacent circuits of the conductive layer; and
deepening the gap in the substrate.

9. The method for manufacturing a probe card of claim 8, wherein the substrate comprises ceramic.

10. The method for manufacturing a probe card of claim 8, wherein the conductive layer further comprises an electroplating layer.

11. The method for manufacturing a probe card of claim 10, wherein the electroplating layer is formed by an electroplating process.

12. The method for manufacturing a probe card of claim 8, wherein a rotating speed for forming the gap between adjacent circuits of the conductive layer is between 4000 and 12000 rpm.

13. The method for manufacturing a probe card of claim 8, wherein a rotating speed for deepening the gap in the substrate is between 4000 and 12000 rpm.

14. The method for manufacturing a probe card of claim 8, wherein the depth of the gap is between 0.3 mm and 1.5 mm.

15. The method for manufacturing a probe card of claim 8, wherein the depth of the gap is preferably between 0.3 mm and 1.0 mm.
